(19) United States
(12) Patent Application Publication
(10) Pub. No.: US 2018/0292753 A1
(43) Pub. Date: Oct. 11, 2018

(54) COMPOSITION FOR FORMING SILICON-CONTAINING FILM FOR EUV LITHOGRAPHY, SILICON-CONTAINING FILM FOR EUV LITHOGRAPHY, AND PATTERN-FORMING METHOD

(71) Applicant: JSR CORPORATION, Minato-ku (JP)

(72) Inventors: Hiromitsu TANAKA, Tokyo (JP); Junya SUZUKI, Tokyo (JP); Ryuichi SERIZAWA, Tokyo (JP); Yuusuke OOTSUBO, Tokyo (JP)

(73) Assignee: JSR CORPORATION, Minato-ku (JP)

(21) Appl. No.: 15/928,806

(22) Filed: Mar. 22, 2018

(30) Foreign Application Priority Data
Mar. 23, 2017 (JP) 2017-057890
Mar. 19, 2018 (JP) 2018-050581

(51) Int. Cl. G03F 7/075; G03F 7/11; G03F 7/09; H01L 21/311; C09D 183/04

(52) U.S. Cl. CPC G03F 7/0757; G03F 7/11; G03F 7/094; C08K 5/42; H01L 21/31138; C09D 183/04; H01L 21/31144

(57) ABSTRACT

Provided are: a composition for forming a silicon-containing film for EUV lithography capable of forming a silicon-containing film that is superior in an outgas-inhibiting property and enables formation of a resist pattern with a superior collapse-inhibiting property and a favorable configuration; a silicon-containing film for EUV lithography; and a pattern-forming method. The composition for forming a silicon-containing film for EUV lithography contains: a polysiloxane; a compound having an onium cation and a sulfonate anion; and a solvent, in which a sum of atomic masses of the atoms constituting the sulfonate anion is no less than 240, the sulfonate anion has a sulfonate group, and a carbon atom adjacent to the sulfonate group, and a fluorine atom does not bond to the carbon atom.

### BACKGROUND OF THE INVENTION

### Field of Invention

The present invention relates to a composition for forming a silicon-containing film for EUV lithography, a silicon-containing film for EUV lithography, and a pattern-forming method.

### Description of the Related Art

In manufacturing semiconductor devices, multilayer resist processes have been employed for attaining a high degree of integration. In these processes, a silicon-containing film is formed first on one face side of a substrate by using a composition for silicon-containing film formation containing polysiloxane, and a resist pattern is formed on the silicon-containing film on a face side opposite to the substrate-facing side, by using a resist composition. The silicon-containing film is then etched by using the resist pattern as a mask, and the substrate is further etched by using the silicon-containing film pattern thus obtained, as a mask to form a desired pattern on the substrate.

Recently, enhanced integration of semiconductor devices is further in progress, and the wavelength of the exposure light to be used tends to be shortened from a KrF excimer laser beam (248 nm) or an ArF excimer laser beam (193 nm) to extreme ultraviolet ray (13.5 nm, EUV).

Under such circumstances, a sulfonic acid onium salt is contained in the silicon-containing film for EUV lithography applications (see PCT International Publication No. 2014/021256).

### PRIOR ART DOCUMENTS

### Patent Documents

Patent Document 1: PCT International Publication No. 2014/021256

### SUMMARY OF THE INVENTION

However, since exposure is carried out in vacuo in EUV lithography, in cases where the composition for silicon-containing film formation conventionally employed is used, substances derived from the silicon-containing film are generated as outgas, leading to contamination of a projection mirror, a mask, etc., of the EUV lithography device. Thus, resolving power of the EUV lithography device may be declined, and consequently, a disadvantage of impairing resolution of the resist pattern formed on the silicon-containing film may be caused.

The present invention was made in view of the foregoing circumstances, and an object of the present invention is to provide a composition for forming a silicon-containing film for EUV lithography capable of forming a silicon-containing film that is superior in an outgas-inhibiting property and enables formation of a resist pattern exhibiting a superior collapse-inhibiting property and having a favorable configuration, and to also provide a silicon-containing film for EUV lithography and a pattern-forming method.

According to one aspect of the invention made for solving the aforementioned problems, a composition for forming a silicon-containing film for EUV lithography contains: a polysiloxane; a compound having an onium cation and a sulfonate anion; and a solvent, in which a sum of atomic masses of atoms constituting the sulfonate anion is no less than 240, the sulfonate anion has a sulfonate group and a carbon atom adjacent to the sulfonate group, and a fluorine atom does not bond to the carbon atom.

According to another aspect of the invention made for solving the aforementioned problems, a silicon-containing film for EUV lithography is formed from the composition for forming a silicon-containing film for EUV lithography.

According to still another aspect of the invention made for solving the aforementioned problems, a pattern-forming method includes: applying the composition for forming a silicon-containing film for EUV lithography onto an upper face side of a substrate; and patterning a silicon-containing film formed after the applying.

The composition for forming a silicon-containing film for EUV lithography of the one aspect of the present invention is capable of forming a silicon-containing film superior in an outgas-inhibiting property, and such a superior silicon-containing film enables a projection mirror, a mask, etc., of the EUV lithography device to be prevented from contamination and also enables formation of a resist pattern exhibiting a superior collapse-inhibiting property and having a favorable configuration. The silicon-containing film for EUV lithography of the another aspect of the invention is superior in an outgas-inhibiting property and enables formation of a resist pattern exhibiting a superior collapse-inhibiting property and having a favorable configuration. According to the pattern-forming method of the still another aspect of the invention, since a silicon-containing film that is superior in an outgas-inhibiting property and enables formation of a resist pattern exhibiting a superior collapse-inhibiting property and having a favorable configuration is formed, forming a desired substrate pattern having a favorable configuration is enabled. Therefore, these can be suitably used for EUV lithography, and can be suitably used for manufacture, etc., of semiconductor devices in which further progress of miniaturization is expected in the future.

### DESCRIPTION OF THE EMBODIMENTS

Hereinafter, a composition for forming a silicon-containing film for EUV lithography (hereinafter, may be merely referred to as “composition for silicon-containing film formation”), a silicon-containing film for EUV lithography (hereinafter, may be merely referred to as “silicon-containing film”) and a pattern-forming method according to embodiments of the present invention will be described.

### Composition for Silicon-Containing Film Formation

The composition for silicon-containing film formation contains: a polysiloxane (hereinafter, may be also referred to as “(A) polysiloxane” or “polysiloxane (A)”); a compound (hereinafter, may be also referred to as “(B) compound” or “compound (B)”) having an onium cation (hereinafter, may be also referred to as “onium cation (X)”) and a sulfonate anion (hereinafter, may be also referred to as “sulfonate anion (Y)”); and a solvent (hereinafter, may be also referred to as “(C) solvent” or “solvent (C)”), in which: a sum of atomic masses of atoms constituting the sulfonate anion (Y) is no less than 240; the sulfonate anion (Y) has a sulfonate group and a carbon atom adjacent to the sulfonate group; and a fluorine atom does not bond to the carbon atom.

The composition for silicon-containing film formation is capable of forming a silicon-containing film that is superior in an outgas-inhibiting property and enables formation of a resist pattern with a superior collapse-inhibiting property and a favorable configuration. Therefore, the composition for silicon-containing film formation can be suitably used for EUV lithography.

The composition for silicon-containing film formation may contain optional component(s) in addition to the polysiloxane (A), the compound (B) and the solvent (C), within a range not leading to impairment of the effects of the present invention. Hereinafter, each component will be described.

### (A) Polysiloxane

The polysiloxane (A) is a polymer having a siloxane bond. The polysiloxane (A) has, for example, a structural unit (I) represented by the following formula (A), a structural unit (II) represented by the following formula (B), and the like. The polysiloxane (A) may have a structural unit other than the structural units (I) and (II), within a range not leading to impairment of the effects of the present invention. Each structural unit is described below.

Structural Unit (I)

The structural unit (I) is represented by the following formula (A). Due to the polysiloxane (A) having the structural unit (I), the composition for silicon-containing film formation enables a variety of characteristics of the silicon-containing film to be optimized.

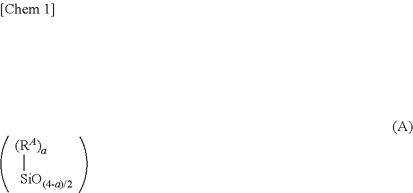

In the above formula (A), R^{A} represents a monovalent organic group having 1 to 20 carbon atoms; and a is an integer of 1 to 3, wherein in a case where a is no less than 2, a plurality of R^{A}s are identical or different.

The monovalent organic group represented by R^{A} is exemplified by: a monovalent hydrocarbon group having 1 to 20 carbon atoms; a group (a) having a divalent hetero atom-containing group between two adjacent carbon atoms of the monovalent hydrocarbon group having 1 to 20 carbon atoms; a group ((3) obtained from the monovalent hydrocarbon group having 1 to 20 carbon atoms, or the group (α) having the divalent hetero atom-containing group by substituting a part or all of hydrogen atoms included therein with a monovalent hetero atom-containing group; and the like.

Exemplary monovalent hydrocarbon group having 1 to 20 carbon atoms includes a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

Examples of the monovalent chain hydrocarbon group having 1 to 20 carbon atoms include groups obtained by removing one hydrogen atom from: alkanes such as methane, ethane, propane and butane; alkenes such as ethene, propene and butene; alkynes such as ethyne, propyne and butyne; and the like.

Examples of the monovalent alicyclic hydrocarbon group having 3 to 20 carbon atoms include groups obtained by removing one hydrogen atom from: alicyclic saturated hydrocarbons, e.g., cycloalkanes such as cyclopentane and cyclohexane, and bridged cyclic saturated hydrocarbons such as norbornane, adamantane and tricyclodecane; alicyclic unsaturated hydrocarbons, e.g., cycloalkenes such as cyclopentene and cyclohexene, and bridged cyclic unsaturated hydrocarbons such as norbornene and tricyclodecene; and the like.

Examples of the monovalent aromatic hydrocarbon group having 6 to 20 carbon atoms include groups obtained by removing one hydrogen atom from 2 to 4 aromatic rings or one hydrogen atom from an aromatic ring and an alkyl group of arenes such as benzene, toluene, ethylbenzene, xylene, naphthalene, methylnaphthalene, anthracene and methylanthracene, and the like.

Examples of the hetero atom constituting the divalent or monovalent hetero atom-containing group include an oxygen atom, a nitrogen atom, a sulfur atom, a phosphorus atom, a silicon atom, a halogen atom, and the like. Examples of the halogen atom include a fluorine atom, a chlorine atom, a bromine atom, an iodine atom, and the like.

The divalent hetero atom-containing group is exemplified by —O—, —CO—, —S—, —CS—, —NR′—, a group obtained by combining two or more of these, or the like, wherein R′ represents a hydrogen atom or a monovalent hydrocarbon group. Of these, —O— and —S— are preferred.

Examples of the monovalent hetero atom-containing group include halogen atoms such as a fluorine atom, a chlorine atom, a bromine atom and an iodine atom, a hydroxy group, a carboxy group, a cyano group, an amino group, a sulfanyl group, and the like.

R^{A} represents preferably a monovalent chain hydrocarbon group, a monovalent aromatic hydrocarbon group or a group obtained from the monovalent hydrocarbon group by substituting a part or all of hydrogen atoms included therein with a monovalent hetero atom-containing group, more preferably an alkyl group, or a fluorine-substituted or unsubstituted aryl group, and still more preferably a methyl group, a phenyl group or a fluorophenyl group.

In a case where the polysiloxane (A) has the structural unit (I), the lower limit of the proportion of the structural unit (I) contained with respect to the total structural units constituting the polysiloxane (A) is preferably 0.1 mol %, more preferably 1 mol %, still more preferably 2 mol %, particularly preferably 5 mol %, and more particularly preferably 8 mol %. The upper limit of the proportion of is preferably 80 mol %, more preferably 50 mol %, still more preferably 30 mol %, and particularly preferably 20 mol %. When the proportion of the structural unit (I) falls within the above range, further optimizing a variety of characteristics of the silicon-containing film is enabled.

Structural Unit (II)

The structural unit (II) is represented by the following formula (B). Due to the polysiloxane (A) having the structural unit (II), the composition for silicon-containing film formation enables resistance of a silicon-containing film to etching by oxygen-based gas to be more enhanced.

[Chem 2]

SiO_{4/2} (B)

Examples of the monomer that gives the structural unit (II) include: tetraalkoxysilanes such as tetramethoxysilane and tetraethoxysilane; tetrahalosilanes such as tetrachlorosilane and tetrabromosilane; and the like.

In a case where the polysiloxane (A) has the structural unit (II), the lower limit of the proportion of the structural unit (II) contained with respect to the total structural units constituting the polysiloxane (A) is preferably 1 mol %, more preferably 10 mol %, still more preferably 30 mol %, and particularly preferably 60 mol %. The upper limit of the proportion is preferably 95 mol %, more preferably 90 mol %, still more preferably 85 mol %, and particularly preferably 80 mol %. When the proportion of the structural unit (II) falls within the above range, the composition for silicon-containing film formation is capable of further enhancing the resistance of the silicon-containing film to etching by oxygen-based gas.

### Other Structural Unit

Examples of other structural unit include those derived from a silane monomer containing a plurality of silicon atoms such as hexamethoxydisilane, bis(trimethoxysilyl)methane and polydimethoxymethylcarbosilane, and the like. When the polysiloxane (A) has the other structural unit, the upper limit of the proportion of the other structural unit contained with respect to the total structural units constituting the polysiloxane (A) is preferably 10 mol %, more preferably 5 mol %, still more preferably 2 mol %, and particularly preferably 1 mol %.

The lower limit of the content of the polysiloxane (A) with respect to the total solid content of the composition for silicon-containing film formation is preferably 50% by mass, more preferably 80% by mass, still more preferably 90% by mass, and particularly preferably 95% by mass. The upper limit of the content is preferably 100% by mass, preferably 99% by mass, and more preferably 97% by mass. The solid content of the composition for silicon-containing film formation as referred to means a sum total of components other than the solvent (B). Either only one type, or two or more types of the polysiloxane (A) may be contained.

The lower limit of the weight average molecular weight (Mw) of the polysiloxane (A) is preferably 1,000, more preferably 1,300, still more preferably 1,500, and particularly preferably 1,700. The upper limit of the Mw is preferably 100,000, more preferably 20,000, still more preferably 7,000, and particularly preferably 3,000.

The Mw of the polysiloxane (A) herein denotes a value determined by gel permeation chromatography (detector: differential refractometer) by using GPC columns available from Tosoh Corporation (“G2000HXL”×2, “G3000HXL”×1 and “G4000HXL”×1), under an analytical condition involving a flow rate of 1.0 mL/min, an elution solvent of tetrahydrofuran and a column temperature of 40° C., with mono-dispersed polystyrene as a standard.

The polysiloxane (A) can be obtained by a process of hydrolytic condensation of a hydrolyzable silane monomer that corresponds to each structural unit described above. By the hydrolytic condensation reaction, each hydrolyzable silane monomer is considered to be incorporated in a polysiloxane irrespective of the type thereof, and thus the proportion of the structural units (I) and (II) and the other structural unit contained in the synthesized polysiloxane (A) would be typically equivalent to the proportion of the amount of each monomer compound used for the synthesis reaction.

### (B) Compound

The compound (B) has the onium cation (X) and the sulfonate anion (Y). The compound (B) generates a hydron (H⁺) through degradation of the onium cation (X) by irradiation with a radioactive ray and/or heating, and in turn a sulfonic acid is generated from the hydron and the sulfonate anion (Y). The sulfonate anion (Y) and the onium cation (X) are described below.

### Sulfonate Anion (Y)

The sulfonate anion (Y) has a sulfonate group and a carbon atom adjacent to the sulfonate group, and a fluorine atom does not bond to the carbon atom. The sulfonate anion (Y) may be monovalent, or divalent or multivalent (i.e., an anion having a plurality of sulfonate groups), but monovalent anions are preferred. It is to be noted that in a case where the sulfonate anion (Y) has a plurality of sulfonate groups, a fluorine atom does not bond to the carbon atom adjacent to any of the sulfonate groups.

The lower limit of the sum of the atomic masses of the atoms constituting the sulfonate anion (Y) may be 240, and is preferably 260, more preferably 290, still more preferably 330, particularly preferably 370, further particularly preferably 400 and most preferably 440. The upper limit of the sum is, for example, 1,000, and preferably 600.

Due to the sum of the atomic masses of the sulfonate anion (Y) falling within the above range, the composition for silicon-containing film formation enables a degree of volatilization of generated sulfonic acid to be lowered, and as a result, an improvement of the outgas-inhibiting property is enabled. In addition, a reduction of contamination, etc., of an exposure system in EUV lithography is thus enabled, and therefore it is considered that attaining favorable collapse-inhibiting property and configuration of the resist pattern is enabled.

The monovalent sulfonate anion (Y) is, for example, represented by the following formula (1).

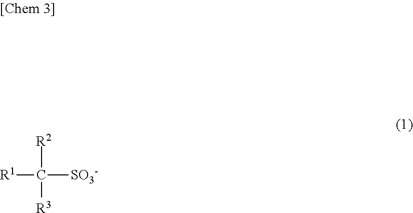

In the above formula (1), R¹ represents a monovalent organic group having 1 to 20 carbon atoms; and R² and R³ each independently represent a hydrogen atom or a methyl group, or two or more of R¹, R² and R³ are taken together represent a ring structure having 3 to 20 ring atoms together with the carbon atom to which the two or more of R¹, R² and R³ bond, wherein a sum of the atomic masses of the atoms constituting R¹, R² and R³ is no less than 148.

The monovalent organic group having 1 to 20 carbon atoms represented by R¹ is exemplified by similar groups to those exemplified for the monovalent organic group represented by R^{A} in the above formula (A), and the like. R¹ represents preferably a group (β) including —COO— between two adjacent carbon atoms of a monovalent alicyclic hydrocarbon group having 8 to 19 carbon atoms, and a group obtained by substituting with a fluorine atom a part of hydrogen atoms included in the group (β), as well as a group (γ) obtained by substituting with 7 or more fluorine atoms a part or all of hydrogen atoms included in a monovalent chain hydrocarbon group having 1 to 20 carbon atoms, and a group obtained by substituting with a hydroxy group a part of hydrogen atoms included in the group (γ), and more preferably a 1-cyclohexylcarbonyloxyethyl group, a 1-cyclohexylcarbonyloxy-2,2,2-trifluoroethyl group, a 1-adamantyloxycarbonyl-2,2,2-trifluoroethyl group, a 2-perfluorohexyl-1-hydroxyethyl group and a perfluoropropyl group.

R² and R³ each preferably represent a hydrogen atom.

Examples of the ring structure having 3 to 20 ring atoms which may be taken together represented by two or more of R¹, R² and R³ include: alicyclic structures, e.g., monocyclic saturated alicyclic structures such as a cyclohexane structure, a cycloheptane structure, a cyclooctane structure, a cyclononane structure, a cyclodecane structure and a cyclododecane structure; monocyclic unsaturated alicyclic structures such as a cyclohexene structure, a cycloheptene structure, a cyclooctene structure and a cyclodecene structure; saturated bridged ring structures such as a norbornane structure, an adamantane structure, a tricyclodecane structure and a tetracyclododecane structure; and unsaturated bridged ring structures such as a norbornene structure and a tricyclodecene structure; aromatic carbon ring structures such as a benzene structure, a naphthalene structure, a phenanthrene structure and an anthracene structure; aliphatic hetero ring structures, e.g., lactone structures such as a hexanolactone structure and a norbornanelactone structure; sultone structures such as a hexanosultone structure and a norbornanesultone structure; oxygen atom-containing hetero ring structures such as an oxacycloheptane structure and an oxanorbornane structure; nitrogen atom-containing hetero ring structures such as an azacyclohexane structure and a diazabicyclooctane structure; and sulfur atom-containing hetero ring structures such as a thiacyclohexane structure and a thianorbornane structure; aromatic hetero ring structures, e.g., oxygen atom-containing hetero ring structures such as a pyran structure, a benzofuran structure and a benzopyran structure; nitrogen atom-containing hetero ring structures such as a pyridine structure, a pyrimidine structure and an indole structure; and the like. Of these, alicyclic structures are preferred, saturated bridged ring structures are more preferred, and a norbornane structure is still more preferred.

Examples of the sulfonate anion (Y) include anions represented by the following formulae (Y-1) to (Y-6), and the like.

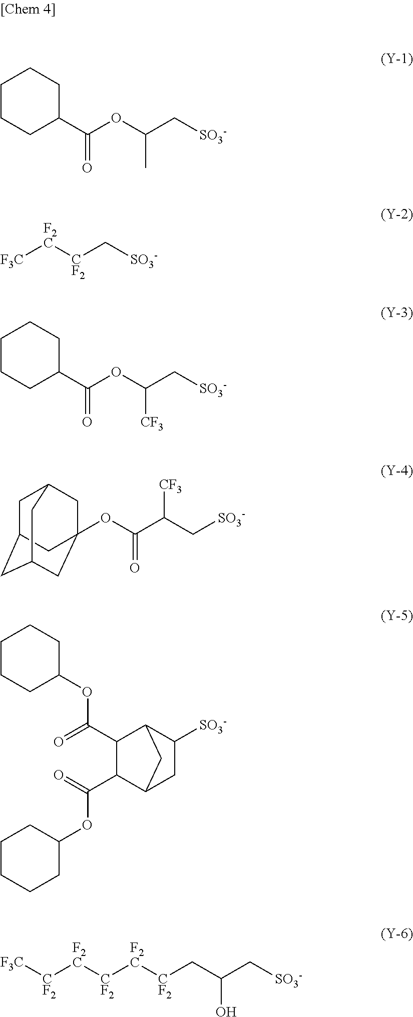

Of these, the sulfonate anions (Y-2) to (Y-6) are preferred, and the sulfonate anions (Y-3) to (Y-5) are more preferred.

### Onium Cation (X)

The onium cation (X) has positive charge in at least one atom such as S, I, O, N, P, Cl, Br, F, As, Se, Sn, Sb, Te and Bi, for example. Of these, preferred atoms include S, I and N, and more preferred atoms include S and I. The onium cation (X) may be monovalent, or divalent or multivalent (i.e., a cation having a plurality of atoms having positive charge), but monovalent cations are preferred.

The onium cation (X) is exemplified by a sulfonium cation, an iodonium cation, an ammonium cation, and the like.

Examples of the monovalent sulfonium cation include: triphenyl-containing sulfonium cations such as a triphenylsulfonium cation, a 4-cyclohexylphenyldiphenylsulfonium cation, a 4-t-butylphenyldiphenylsulfonium cation and a tri(4-t-butylphenyl)sulfonium cation; tetrahydrothiophenium cations such as a 1-(4-n-butoxynaphthalen-1-yl)tetrahydrothiophenium cation and a 1-(3,5-dimethyl-4-hydroxyphenyl)tetrahydrothiophenium cation; and the like.

Examples of the monovalent iodonium cation include a diphenyliodonium cation, a bis(4-t-butylphenyl)iodonium cation, and the like.

Examples of the monovalent ammonium cation include a tetramethylammonium cation, a tetraethylammonium cation, a tetraphenylammonium cation, and the like.

Of these, the sulfonium cation and the iodonium cation are preferred, the triphenyl-containing sulfonium cation and the iodonium cation are more preferred, and a triphenylsulfonium cation and a diphenyliodonium cation are still more preferred.

The lower limit of the content of the compound (B) with respect to 100 parts by mass of the polysiloxane (A) is preferably 0.1 parts by mass, more preferably 0.5 parts by mass, still more preferably 1 part by mass, and particularly preferably 2 parts by mass. The upper limit of the content is preferably 30 parts by mass, more preferably 20 parts by mass, still more preferably 10 parts by mass, and particularly preferably 5 parts by mass. When the content of the compound (B) falls within the above range, further improvements of an outgas-inhibiting property, a pattern collapse-inhibiting property and favorableness of pattern configuration are enabled.

### (C) Solvent

The solvent (C) is not particularly limited as long as the polysiloxane (A) and the compound (B), and an optional component that is to be contained as needed can be dissolved or dispersed therein. The solvent (C) is exemplified by an alcohol solvent, a ketone solvent, an ether solvent, an ester solvent, a nitrogen-containing solvent, water, and the like. The solvent (C) may bae used either alone of one type, or in combination of two or more types thereof.

Examples of the alcohol solvent include: monohydric alcohol solvents such as methanol, ethanol, n-propanol, iso-propanol, n-butanol and iso-butanol; polyhydric alcohol solvents such as ethylene glycol, 1,2-propylene glycol, diethylene glycol and dipropylene glycol; and the like.

Examples of the ketone solvent include acetone, methyl ethyl ketone, methyl n-propyl ketone, methyl iso-butyl ketone, cyclohexanone, and the like.

Examples of the ether solvent include ethyl ether, iso-propyl ether, ethylene glycol dibutyl ether, diethylene glycol monomethyl ether, diethylene glycol monoethyl ether, diethylene glycol diethyl ether, propylene glycol monomethyl ether, propylene glycol monoethyl ether, propylene glycol monopropyl ether, tetrahydrofuran, and the like.

Examples of the ester solvent include ethyl acetate, γ-butyrolactone, n-butyl acetate, ethylene glycol monomethyl ether acetate, ethylene glycol monoethyl ether acetate, diethylene glycol monomethyl ether acetate, diethylene glycol monoethyl ether acetate, propylene glycol monomethyl ether acetate, propylene glycol monoethyl ether acetate, dipropylene glycol monomethyl ether acetate, dipropylene glycol monoethyl ether acetate, ethyl propionate, n-butyl propionate, methyl lactate, ethyl lactate, and the like.

Examples of the nitrogen-containing solvent include N,N-dimethylformamide, N,N-dimethylacetamide, N-methylpyrrolidone, and the like.

Of these, the ether solvent, the ester solvent and water are preferred, and an ether solvent and an ester solvent each having a glycol structure are more preferred due to superior film formability.

Examples of the ether solvent and the ester solvent each having a glycol structure include propylene glycol monomethyl ether, propylene glycol monoethyl ether, propylene glycol monopropyl ether, propylene glycol monomethyl ether acetate, propylene glycol monoethyl ether acetate, propylene glycol monopropyl ether acetate, and the like.

The lower limit of the percentage content of the ether solvent and the ester solvent each having a glycol structure in the solvent (C) is preferably 20% by mass, more preferably 60% by mass, still more preferably 90% by mass, and particularly preferably 100% by mass.

The lower limit of the content of the solvent (C) in the composition for silicon-containing film formation is preferably 80% by mass, more preferably 90% by mass, and still more preferably 95% by mass. The upper limit of the content is preferably 99% by mass, and more preferably 98% by mass.

### Optional Component

The composition for silicon-containing film formation may contain, for example, an acid generating agent, a surfactant, etc., as an optional component.

### Acid Generating Agent

The acid generating agent is a compound that generates an acid upon heating and/or irradiation with an ultraviolet ray. The acid generating agent may be used either alone of one type, or in combination of two or more types thereof.

The acid generating agent is exemplified by a an onium salt compound, a N-sulfonyloxyimide compound, and the like.

Exemplary onium salt compound includes a sulfonium salt, a tetrahydrothiophenium salt, an iodonium salt, an ammonium salt, and the like.

Examples of the sulfonium salt include triphenylsulfonium trifluoromethanesulfonate, triphenylsulfonium nonafluoro-n-butanesulfonate, 4-cyclohexylphenyldiphenylsulfonium trifluoromethanesulfonate, and the like.

Examples of the tetrahydrothiophenium salt include those described in paragraph [0111] of Japanese Unexamined Patent Application, Publication No. 2014-037386, and specific examples include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium 2-bicyclo[2.2.1]hept-2-yl-1,1,2,2-tetrafluoroethanesulfonate, and the like.

Examples of the iodonium salt include those described in paragraph [0112] of Japanese Unexamined Patent Application, Publication No. 2014-037386, and specific examples include diphenyliodonium trifluoromethanesulfonate, diphenyliodonium nonafluoro-n-butanesulfonate, diphenyliodonium 2-bicyclo[2.2.1]hept-2-yl-1,1,2,2-tetrafluoroethanesulfonate, bis(4-t-butylphenyl)iodonium nonafluoro-n-butanesulfonate, and the like.

Examples of the ammonium salt include trimethylammonium nonafluoro-n-butanesulfonate, triethylammonium nonafluoro-n-butanesulfonate, and the like.

Examples of the N-sulfonyloxyimide compound include those described in paragraph [0113] of Japanese Unexamined Patent Application, Publication No. 2014-037386, and specific examples include N-(trifluoromethanesulfonyloxy)bicyclo[2.2.1]hept-5-ene-2,3-dicarboxyimide, N-(nonafluoro-n-butanesulfonyloxy)bicyclo[2.2.1]hept-5-ene-2,3-dicarboxyimide, N-(2-bicyclo[2.2.1]hept-2-yl-1,1,2,2-tetrafluoroethanesulfonyloxy)bicyclo[2.2.1]hept-5-ene-2,3-dicarboxyimide, and the like.

When the composition for silicon-containing film formation contains the acid generating agent, the lower limit of the content of the acid generating agent with respect to 100 parts by mass of the polysiloxane (A) is preferably 0.01 parts by mass, more preferably 0.1% by mass, still more preferably 0.5 parts by mass, and particularly preferably 1 part by mass. The upper limit of the content is preferably 10 parts by mass, more preferably 5 parts by mass, and still more preferably 1 part by mass.

When the composition for silicon-containing film formation contains the other optional component except for the acid generating agent, the upper limit of the content thereof with respect to 100 parts by mass of the polysiloxane (A) is preferably 1 part by mass, more preferably 0.5 parts by mass, and still more preferably 0.1 parts by mass.

### Preparation Method of Composition for Silicon-Containing Film Formation

The preparation method of the composition for silicon-containing film formation is not particularly limited, and the composition can be prepared by, for example, mixing the polysiloxane (A), the compound (B) and the solvent (C), and the optional component that is to be contained as needed at a certain ratio, preferably followed by filtration of the resulting mixed solution through a filter having a pore size of 0.2 μm.

The lower limit of the solid content concentration of the composition for silicon-containing film formation is preferably 0.01% by mass, more preferably 0.05% by mass, still more preferably 0.1% by mass, and particularly preferably 0.2% by mass. The upper limit of the solid content concentration is preferably 20% by mass, more preferably 10% by mass, still more preferably 5% by mass, and particularly preferably 3% by mass. The solid content concentration of the composition for silicon-containing film formation as referred to means a value (% by mass) determined by: baking the composition for silicon-containing film formation at 250° C. for 30 min; measuring the mass of the solid content in the composition; and dividing the mass of this solid content by the mass of the composition for silicon-containing film formation.

### Silicon-Containing Film

The silicon-containing film of the present invention is formed from the composition for silicon-containing film formation. Since the silicon-containing film is formed from the aforementioned composition for silicon-containing film formation, the silicon-containing film is superior in the outgas-inhibiting property and enables formation of a resist pattern exhibiting a superior collapse-inhibiting property and having a favorable configuration.

The silicon-containing film may be formed by applying the aforementioned composition for silicon-containing film formation onto a surface of the substrate, other underlayer film such as an organic underlayer film, or the like to provide a coating film, and hardening the coating film by heating.

A procedure for applying the composition for silicon-containing film formation may involve, for example, spin coating, roll coating, dip coating, and the like. The lower limit of the heat treatment temperature is preferably 50° C., and more preferably 70° C. The upper limit of the heat treatment temperature is preferably 450° C., and more preferably 300° C. The lower limit of the average thickness of the silicon-containing film formed is preferably 5 nm, and more preferably 10 nm. The upper limit of the average thickness is preferably 50 nm, more preferably 20 nm, and still more preferably 15 nm.

### Pattern-Forming Method

The pattern-forming method includes: applying the composition for silicon-containing film formation onto an upper face side of a substrate (hereinafter, may be also referred to as “applying step”); and patterning a silicon-containing film formed after the applying (hereinafter, may be also referred to as “silicon-containing film patterning step”).

The pattern-forming method enables a silicon-containing film that is superior in outgas-inhibiting property and enables formation of a resist pattern exhibiting a superior collapse-inhibiting property and having a favorable configuration to be formed, and such a superior silicon-containing film enables a desired substrate pattern having a favorable configuration to be formed.

The silicon-containing film patterning step may include: applying a resist composition onto an upper face side of the silicon-containing film; exposing to an extreme ultraviolet ray a resist film formed after the applying of the resist composition; developing the resist film exposed; and etching the silicon-containing film using as a mask a resist pattern formed after the developing (hereinafter, may be also referred to as “silicon-containing film etching step”). By further including such steps, the silicon-containing film superior in an outgas-inhibiting property enables a resist pattern exhibiting a collapse-inhibiting property and having a favorable configuration to be formed, and as a result, formation of a more desired substrate pattern having a favorable configuration is enabled.

The pattern-forming method may further include as needed, before the applying step, forming an organic underlayer film on at least the upper face side of the substrate (hereinafter, may be also referred to as “organic underlayer film-forming step”). The pattern-forming method typically includes after the silicon-containing film patterning step, etching the substrate using as a mask the silicon-containing film having been patterned (hereinafter, may be also referred to as “substrate-etching step”). Each step will be described below.

### Organic Underlayer Film-Forming Step

In this step, the organic underlayer film is formed on at least the upper face side of the substrate. In the aforementioned pattern-forming method, the organic underlayer film-forming step may be carried out as needed.

In a case where the organic underlayer film-forming step is carried out in the pattern-forming method, the applying step is carried out after the organic underlayer film-forming step, and the silicon-containing film is formed on the organic underlayer film in this applying step by using the composition for silicon-containing film formation.

The substrate is exemplified by insulating films such as silicon oxide, silicon nitride, silicon nitride oxide and polysiloxane, resin substrates, and the like. Examples of the substrate which may be used include interlayer insulating films such as wafers coated with a low-dielectric insulating film formed from “Black Diamond” available from AMAT, “SiLK” available from Dow Chemical, “LKD5109” available from JSR Corporation or the like. A substrate patterned to have wiring grooves (trenches), plug grooves (vias) or the like may also be used as the substrate.

The organic underlayer film is different from the silicon-containing film formed from the composition for silicon-containing film formation described above. The organic underlayer film serves in further compensating for a function exhibited by the silicon-containing film and/or the resist film in resist pattern formation, as well as in imparting a necessary certain function for attaining the function not exhibited by the silicon-containing film and/or the resist film (for example, antireflective property, coating film flatness, high etching resistance to fluorine-based gas).

The organic underlayer film is exemplified by a antireflective film and the like. An exemplary composition for antireflective film formation may include “NFC HM8006” available from JSR Corporation, and the like.

The organic underlayer film may be formed by applying a composition for organic underlayer film formation through spin coating or the like to form a coating film, and then heating.

### Applying Step

In this step, the aforementioned composition for silicon-containing film formation is applied onto an upper face side of the substrate. By this step, the silicon-containing film is formed on the substrate directly or via other layer such as the organic underlayer film.

A procedure for applying the composition for silicon-containing film formation is not particularly limited, but a procedure of applying the composition for silicon-containing film formation on the substrate or the like by a known method such as, e.g., spin coating may be exemplified. The silicon-containing film is formed by subjecting the coating film formed by the applying step to an exposure and/or heating as needed, thereby allowing for hardening.

Examples of the radioactive ray used for the exposure include electromagnetic waves such as a visible light ray, an ultraviolet ray, a far ultraviolet ray, an X-ray and a γ-ray”, particle rays such as an electron beam, a molecular beam and an ion beam, and the like.

The lower limit of the temperature in heating the coating film is preferably 90° C., more preferably 150° C., and still more preferably 200° C. The upper limit of the temperature is preferably 550° C., more preferably 450° C., and still more preferably 300° C. The lower limit of the average thickness of the silicon-containing film formed is preferably 1 nm, more preferably 10 nm, and still more preferably 20 nm. The upper limit of the average thickness is preferably 20,000 nm, more preferably 1,000 nm, and still more preferably 100 nm.

### Silicon-Containing Film Patterning Step

In this step, the silicon-containing film formed after the applying is patterned. The silicon-containing film formed by the applying step is patterned by this step. An exemplary procedure for patterning the silicon-containing film may includes, e.g., forming a resist pattern on an upper face side of the silicon-containing film (hereinafter, may be also referred to as “resist pattern-forming step”) and etching the silicon-containing film.

### Resist Pattern-Forming Step

In this step, the resist pattern is formed on the upper face side of the silicon-containing film. A procedure for forming the resist pattern is exemplified by conventionally known methods in which a resist composition is used, or nanoimprinting lithography is employed, and the like. The resist pattern is typically formed from an organic material.

An exemplary method in which a resist composition is used may include, for example, applying a resist composition onto an upper face side of the silicon-containing film (hereinafter, may be also referred to as “resist composition-applying step”), exposing the resist film (hereinafter, may be also referred to as “exposure step”), and developing the resist film exposed (hereinafter, may be also referred to as “development step”).

Resist Composition Applying Step

In this step, the resist composition is applied onto an upper face side of the silicon-containing film.

The resist composition is exemplified by a radiation-sensitive resin composition containing a polymer having an acid-labile group and a radiation-sensitive acid generating agent (chemically amplified resist composition), a positive tone resist composition containing an alkali-soluble resin and a quinone diazide-based photosensitizing agent, a negative tone resist composition containing an alkali-soluble resin and a crosslinking agent, and the like. Of these, the radiation-sensitive resin composition is preferred. In a case where the radiation-sensitive resin composition is used, formation of a positive tone pattern is enabled by developing with an alkaline developer solution, whereas formation of a negative tone pattern is enabled by developing with an organic solvent liquid. For forming the resist pattern, double patterning, double exposure or the like which is a procedure for fine pattern formation may be appropriately employed.

The polymer contained in the radiation-sensitive resin composition may have, in addition to a structural unit that includes the acid-labile group, for example, a structural unit that includes a lactone structure, a cyclic carbonate structure and/or a sultone structure, a structural unit that includes an alcoholic hydroxyl group, a structural unit that includes a phenolic hydroxyl group, a structural unit that includes a fluorine atom, etc. When the polymer has the structural unit that includes a phenolic hydroxyl group, and/or the structural unit that includes a fluorine atom, an improvement in sensitivity is enabled in the case of using an extreme ultraviolet ray (EUV), an electron beam or the like as as the radioactive ray in the exposure.

The lower limit of the solid content concentration of the resist composition is preferably 0.1% by mass, and more preferably 1% by mass. The upper limit of the solid content concentration is preferably 50% by mass, and more preferably 30% by mass. The resist composition filtered through a filter having a pore size of about 0.2 μm may be suitably used. In the pattern-forming method, a commercially available resist composition may be directly used as the resist composition.

The resist film may be formed by, for example, applying the resist composition onto the silicon-containing film. A procedure for applying the resist composition may be exemplified by a conventional method such as, e.g., spin coating. In applying the resist composition, the amount of the resist composition to be applied is adjusted such that the resist film obtained has a predetermined film thickness.

The resist film may be formed by prebaking the coating film of the resist composition to allow the solvent in the coating film to be volatilized. The prebaking temperature may be appropriately adjusted depending on the type, etc., of the resist composition used. The lower limit of the prebaking temperature is preferably 30° C., and more preferably 50° C. The upper limit of the prebaking temperature is preferably 200° C., and more preferably 150° C.

Exposure Step

In this step, the resist film is exposed. The exposure is carried out by, for example, selectively irradiating with a radioactive ray through a mask.

The radioactive ray used for the exposure is preferably EUV or an electron beam.

Development Step

In this step, the resist film exposed is developed. Accordingly, the resist pattern is formed.

The development may be either development with an alkali or development with an organic solvent.

Examples of the alkaline developer solution include alkaline aqueous solutions of sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, choline, 1,8-diazabicyclo[5.4.0]-7-undecene, 1,5-diazabicyclo[4.3.0]-5-nonene or the like. Also, these alkaline aqueous solutions may contain, for example, a water soluble organic solvent such as an alcohol, e.g., methanol and ethanol, as well as a surfactant, etc., added in an appropriate amount.

The organic solvent developer solution is exemplified by liquids containing an organic solvent such as a ketone solvent, an alcohol solvent, an amide solvent, an ether solvent or an ester solvent as a principal component, and the like. Examples of the solvent include those similar to the solvents exemplified for the solvent (B) described above, and the like. These solvents may be used wither alone of one type, or as a mixture.

After carrying out the development with the developer solution, washing and drying are preferably conducted. Thus, formation of a predetermined resist pattern corresponding to the photomask is enabled.

### Silicon-Containing Film Etching Step

In this step, by using the resist pattern as a mask, the silicon-containing film is etched. More specifically, a patterned silicon-containing film is obtained by etching once or a plurality of times, with the resist pattern formed in the resist pattern-forming step as a mask.

The etching may be either dry etching or wet etching, and dry etching is preferred.

The dry etching may be carried out by using, for example, a known dry etching apparatus. An etching gas used for the dry etching may be appropriately selected depending on element composition and the like of the silicon-containing film to be etched. Examples of the etching gas which may be used include: fluorine-based gases such as CHF₃, CF₄, C₂F₆, C₃F₈ and SF₆; chlorine-based gases such as Cl₂ and BCl₃; oxygen-based gases such as O₂, O₃ and H₂O; reductive gases such as H₂, NH₃, CO, CO₂, CH₄, C₂H₂, C₂H₄, C₂H₆, C₃H₄, C₃H₆, C₃H₈, HF, HI, HBr, HCl, NO, NH₃ and BCl₃; inert gases such as He, N₂ and Ar; and the like. These gases may be used as a mixture. In dry etching of the silicon-containing film, the fluorine-based gas is typically used, and a mixture obtained by adding an oxygen-based gas and an inert gas to the fluorine-based gas may be suitably used.

### Substrate Etching Step

In this step, by using the patterned silicon-containing film as a mask, the substrate is etched. More specifically, a patterned substrate is obtained by etching once or a plurality of times, with as a mask the pattern formed on the silicon-containing film obtained by the silicon-containing film etching step.

In a case where the organic underlayer film is formed on the substrate, the pattern is formed on the substrate by: using the silicon-containing film pattern as the mask in etching the organic underlayer film to form the pattern of the organic underlayer film; and thereafter using the organic underlayer film pattern as the mask in etching the substrate.

The etching may be either dry etching or wet etching, and dry etching is preferred.

The dry etching in forming the pattern on the organic underlayer film may be carried out by using, for example, a known dry etching apparatus. An etching gas used for the dry etching may be appropriately selected depending on element composition and the like of the silicon-containing film and organic underlayer film to be etched. Examples of the etching gas which may be used include: fluorine-based gases such as CHF₃, CF₄, C₂F₆, C₃F₈ and SF₆; chlorine-based gases such as Cl₂ and BCl₃; oxygen-based gases such as O₂, O₃ and H₂O; reductive gases such as H₂, NH₃, CO, CO₂, CH₄, C₂H₂, C₂H₄, C₂H₆, C₃H₄, C₃H₆, C₃H₈, HF, HI, HBr, HCl, NO, NH₃ and BCl₃; inert gases such as He, N₂ and Ar; and the like. These gases may be used as a mixture. In dry etching of an organic underlayer film with the silicon-containing film pattern as a mask, the oxygen-based gas is typically used.

The dry etching in forming the pattern on the substrate with the organic underlayer film pattern as the mask may be carried out by using, for example, a known dry etching apparatus. An etching gas used for the dry etching may be appropriately selected depending on element composition and the like of the organic underlayer film and the substrate to be etched. For example, etching gases similar to those exemplified as the etching gases which may be used in the dry etching of the organic underlayer film may be exemplified. The etching may be carried out a plurality of times with different etching gases. It is to be noted that after the step of substrate pattern formation, in a case where the silicon-containing film remains on the substrate, on the resist underlayer pattern, etc., the silicon-containing film may be removed by carrying out a step of removing the silicon-containing film which will be described later.

### EXAMPLES

Examples will be demonstrated herein below. It should be noted that the following Examples merely illustrate one typical example of the present invention, and the scope of the present invention should not be construed to be narrowed by the Examples.

In the present Examples, measurements of the solid content concentration in the solution of the polysiloxane (A), and measurements of the weight average molecular weight (Mw) of the polysiloxane (A) were conducted according to the following methods.

### Solid Content Concentration of Solution of Polysiloxane (A)

The solid content concentration (% by mass) of the solution of the polysiloxane (A) was determined by baking 0.5 g of a solution of the polysiloxane (A) at 250° C. for 30 min, and measuring the mass of the solid content in 0.5 g of this solution.

### Weight Average Molecular Weight (Mw)

Measurements were carried out on gel permeation chromatography (detector: differential refractometer) by using GPC columns (“G2000HXL”×2, “G3000HXL”×1, “G4000HXL”×1, available from Tosoh Corporation) under an analytical condition involving: a flow rate of 1.0 mL/min; an elution solvent of tetrahydrofuran; and a column temperature of 40° C., with mono-dispersed polystyrene as a standard.

### Synthesis of Polysiloxane (A)

Monomers used for the synthesis of the polysiloxane (A) are presented below.

It is to be noted that in the following Synthesis Examples, unless otherwise specified particularly, “parts by mass” mean a value, provided that the total mass of the monomers used was 100 parts by mass.

Compounds (M-1) to (M-4): compounds represented by the following formulae (M-1) to (M-4)

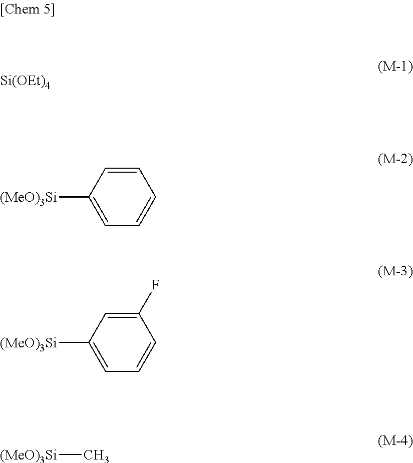

### Synthesis Example 1-1: Synthesis of Polysiloxane (A-1)

In a reaction vessel, a monomer solution was prepared by dissolving the compound represented by the above formula (M-1) and the compound represented by the above formula (M-2) to give a molar ratio of 90/10 (mol %), in 62 parts by mass of propylene glycol monoethyl ether. In the reaction vessel, the temperature was raised to 60° C., and 40 parts by mass of a 9.1% by mass aqueous oxalic acid solution was added dropwise over 20 min with stirring. The time of the start of the dropwise addition was regarded as the time of the start of the reaction, and the reaction was allowed to proceed for 4 hrs. After the completion of the reaction, the reaction vessel was cooled to no greater than 30° C. To the cooled reaction solution were added 52 parts by mass of propylene glycol monoethyl ether. Thereafter, water, alcohols generated by the reaction, and excess propylene glycol monoethyl ether were removed by using an evaporator to give a solution of polysiloxane (A-1) in propylene glycol monoethyl ether. The Mw of the polysiloxane (A-1) was 1,950. The solid content concentration of the propylene glycol monoethyl ether solution of the polysiloxane (A-1) was 12.0% by mass.

### Synthesis Examples 1-2 to 1-4: Synthesis of Polysiloxanes (A-2) to (A-4)

Solutions of polysiloxanes (A-2) to (A-4) in propylene glycol monoethyl ether were obtained in a similar manner to Synthesis Example 1 except that each monomer of the type and amount shown in Table 1 below was used. The Mw and the solid content concentration (% by mass) of each of the polysiloxanes (A) in the solutions of the polysiloxanes (A) thus obtained are shown together in Table 1. The denotation “-” in Table 1 indicates that the corresponding monomer was not used.

TABLE 1

| | | | | | | | Solid con- |
|---|---|---|---|---|---|---|---|
| | (A) | | | | | | tent con- |
| | Poly- | Monomer (mol %) | | | | | centration |
| | siloxane | M-1 | M-2 | M-3 | M-4 | Mw | (% by mass) |
| Synthesis | A-1 | 90 | 10 | — | — | 1,950 | 12.0 |
| Example 1-1 | | | | | | | |
| Synthesis | A-2 | 65 | 10 | — | 25 | 1,650 | 13.5 |
| Example 1-2 | | | | | | | |
| Synthesis | A-3 | 65 | — | 10 | 25 | 1,700 | 13.1 |
| Example 1-3 | | | | | | | |
| Synthesis | A-4 | 50 | — | — | 50 | 2,000 | 12.2 |
| Example 1-4 | | | | | | | |

### Preparation of Composition for Silicon-Containing Film Formation

Components used for the preparation of the composition for silicon-containing film formation, except for the polysiloxane (A), are shown below.

### (B) Compound

### Examples: B-1 to B-8: Compounds Represented by the Following Formulae (B-1) to (B-8)

### Comparative Examples: b-1 to b-3: Compounds Represented by the Following Formulae (b-1) to (b-3)

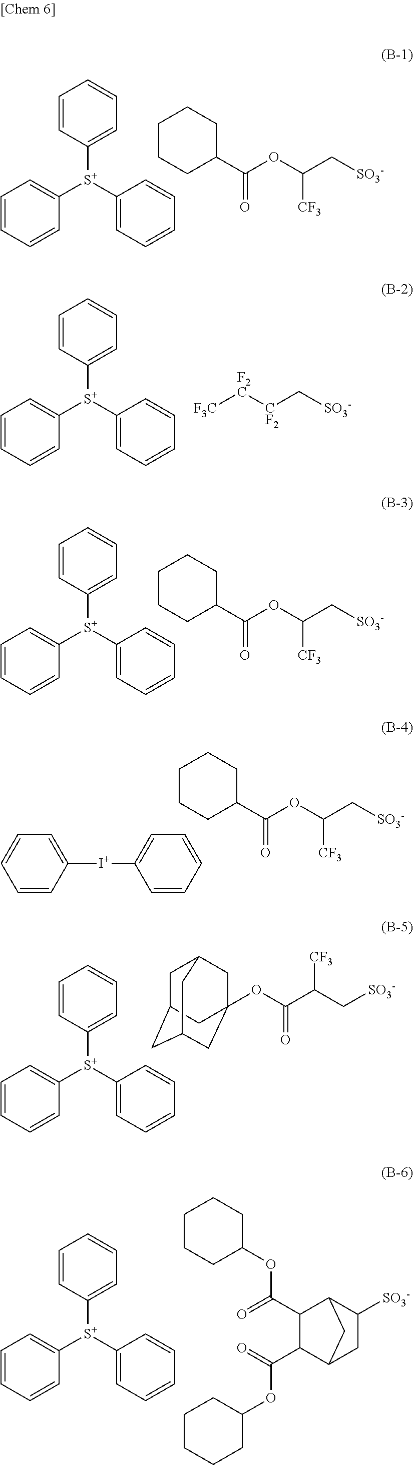

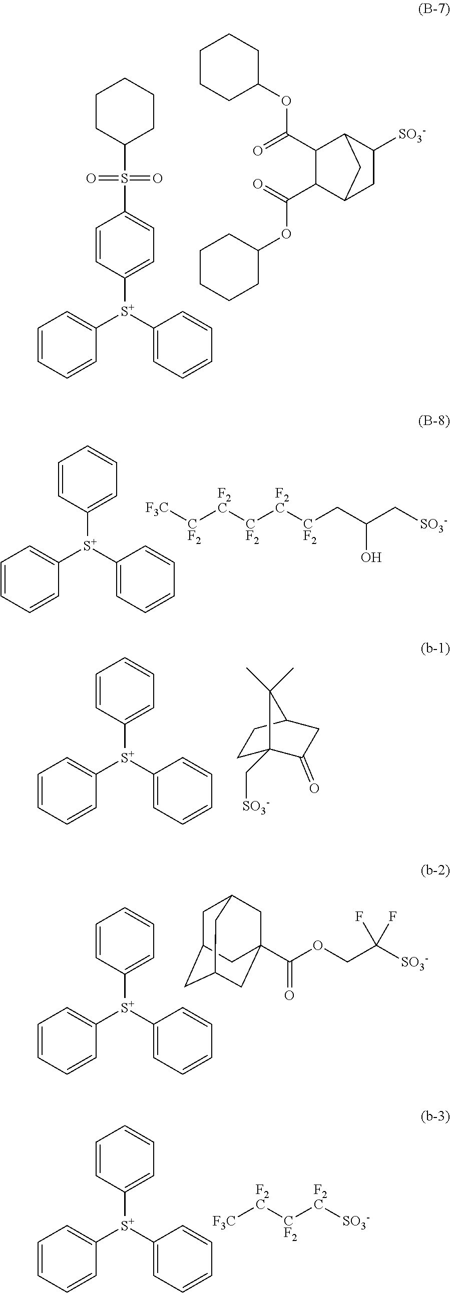

It is to be noted that sum of the atomic masses of atoms constituting the sulfonate anion were: 249 for (B-1), 263 for (B-2), 303 for (B-3), 303 for (B-4), 355 for (B-5), 428 for (B-6), 428 for (B-7), 459 for (B-8), 231 for (b-1), 323 for (b-2), and 318 for (b-3).

### (C) Solvent

C-1: propylene glycol monoethyl ether acetate

C-2: propylene glycol monoethyl ether

C-3: water

### Example 1-1

A composition for silicon-containing film formation (J-1) was prepared by mixing: 0.59 parts by mass of (A-1) as the polysiloxane (A) (solid content); 0.10 parts by mass of (B-1) as the compound (B); and 10 parts by mass of (C-1), 86 parts by mass of (C-2) (including also the solvent (C-2) contained in the polysiloxane (A) solution) and 4 parts by mass of (C-3) as the solvent (C), and then filtering the resulting solution through a filter having a pore size of 0.2 μm.

### Examples 1-2 to 1-11 and Comparative Examples 1-1 to 1-3

Compositions for silicon-containing film formation (J-2) to (J-11) and (j-1) to (j-3) were prepared in a similar manner to Example 1 except that each component of the type and amount shown in Table 2 below was used.

Formation of Silicon-Containing Film

Each composition for silicon-containing film formation prepared as described above was applied onto a silicon wafer (substrate) by spin coating with a spin coater (“CLEAN TRACK ACT12” available from Tokyo Electron Limited). After a coating film thus obtained was heated on a hot plate at 220° C. for 60 sec, cooling at 23° C. for 60 sec gave a substrate having a silicon-containing film having an average thickness of 13 nm formed thereon shown as Examples 1-1 to 1-11 and Comparative Examples 1-1 to 1-3 in Table 2.

### Evaluations

The compositions for silicon-containing film formation prepared as described above and the silicon-containing film formed as described above were evaluated on the following items according to the following methods. The results of the evaluations are shown together in Table 2 below.

### Outgas-Inhibiting Property

Each composition for silicon-containing film formation prepared as described above was applied onto an 8-inch silicon wafer (substrate) by spin coating with a spin coater (“CLEAN TRACK ACTS” available from Tokyo Electron Limited). After a coating film thus obtained was heated on a hot plate at 220° C. for 60 sec, cooling at 23° C. for 60 sec gave a substrate having a silicon-containing film having an average thickness of 13 nm formed thereon. Thereafter, an 8-inch silicon wafer was disposed on a top plate of a hot plate, and heated at 300° C. for 60 sec on the hot plate. After the step was repeated 50 times, the 8-inch silicon wafer disposed on the top plate of the hot plate was washed with cyclohexanone to collect the sublimate deposited on the substrate. The outgas-inhibiting property was evaluated based on the amount of the sublimate, according to the criteria of: “A” (favorable) when the amount was no greater than 1.0 mg; “B” (somewhat favorable) when the amount was greater than 1.0 mg and no greater than 2.0 mg; and “C” (unfavorable) when the amount was greater 2.0 mg.

Collapse Inhibitory Property: Collapse-inhibiting property of positive tone resist pattern on exposure to electron beam or exposure to extreme ultraviolet ray

An antireflective film having an average thickness of 100 nm was formed on an 8-inch silicon wafer by applying a material for forming an antireflective film (“HM8006” available from JSR Corporation) by spin coating with the spin coater, and then heating at 250° C. for 60 sec. A silicon-containing film having an average thickness of 13 nm was formed by applying the composition for silicon-containing film formation onto the antireflective film and heating at 220° C. for 60 sec, followed by cooling at 23° C. for 30 sec.

Next, a resist film having an average thickness of 50 nm was formed by applying a radiation-sensitive resin composition described later onto the silicon-containing film thus formed, and heating at 130° C. for 60 sec, followed by cooling at 23° C. for 30 sec.

The radiation-sensitive resin composition was obtained by mixing: 100 parts by mass of a polymer having a structural unit (1) derived from 4-hydroxystyrene, a structural unit (2) derived from styrene and a structural unit (3) derived from 4-t-butoxystyrene (proportion of each structural unit contained: (1)/(2)/(3)=65/5/30 (mol %)); 2.5 parts by mass of triphenylsulfonium salicylate as a radiation-sensitive acid generating agent; and as solvents, 1,500 parts by mass of ethyl lactate and 700 parts by mass of propylene glycol monomethyl ether acetate, and filtering the resulting solution through a filter having a pore size of 0.2 μm.

In the case of the exposure to an electron beam, the resist film was irradiated with the electron beam by using an electron beam writer (“HL800D” available from Hitachi, Ltd., output: 50 KeV, electric current density: 5.0 ampere/cm²). After the irradiation with the electron beam, the substrate was heated at 110° C. for 60 sec, and then cooled at 23° C. for 60 sec. Thereafter, a 2.38% by mass aqueous TMAH solution (20 to 25° C.) was used to carry out a development according to a puddle procedure. Subsequently, washing with water, followed by drying gave a resist-patterned substrate for evaluation. In the resist pattern formation, an exposure dose at which a 1:1 line-and-space pattern was formed with a line width of 150 nm was defined as “optimal exposure dose”. For a line-width measurement and inspection of the resist pattern of the substrate for evaluation, a scanning electron microscope (“CG-4000” available from Hitachi High-Technologies Corporation) was employed. The collapse-inhibiting property was evaluated, at the optimum exposure dose, as: “A” (favorable) when pattern collapse was not found; and “B” (unfavorable) when pattern collapse was found.

In the case of the exposure to an extreme ultraviolet ray, the resist film was exposed by using an BUY scanner (“TWINSCAN NXE: 3300B” available from ASML (NA: 0.3, Sigma: 0.9, quadle pole illumination, mask of a 1:1 line-and-space pattern with a line width of 25 nm in terms of dimension on the wafer)). After the exposure, the substrate was heated at 110° C. for 60 sec, and then cooled at 23° C. for 60 sec. Thereafter, a 2.38% by mass aqueous TMAH solution (20 to 25° C.) was used to carry out a development according to a puddle procedure. Subsequently, washing with water, followed by drying gave a resist-patterned substrate for evaluation. In the resist pattern formation, an exposure dose at which a 1:1 line-and-space pattern was formed with a line width of 25 nm was defined as “optimal exposure dose”. For a line-width measurement and inspection of the resist pattern of the substrate for evaluation, a scanning electron microscope (“CG-4000” available from Hitachi High-Technologies Corporation) was employed. The collapse-inhibiting property was evaluated, at the optimum exposure dose, as: “A” (favorable) when pattern collapse was not observed; and “B” (unfavorable) when pattern collapse was observed.

Pattern Configuration

For the configuration of the resist pattern, the evaluation was made as: “A” (favorable) when tailing was absent; and “B” (unfavorable) when tailing was present.

TABLE 2

| | Compo- | | | | | | | Results of evaluations | | | | |
|---|---|---|---|---|---|---|---|---|---|---|---|---|
| | sition for | (A) Polysiloxane | | | | | | | | | Extreme ultraviolet | |
| | silicon- | | parts by | | | | | | Electron beam exposure | | ray exposure | |
| | containing | | mass | (B) Compound | | (C) Solvent | | Outgas- | Collapse- | Pattern | Collapse- | Pattern |
| | film | | (solid | | parts by | | parts by | inhibiting | inhibiting | configu- | inhibiting | configu- |
| | formation | type | content) | type | mass | type | mass | property | property | ration | property | ration |
| Example 1-1 | J-1 | A-1 | 0.59 | B-1 | 0.10 | C-1/C-2/C-3 | 10/86/4 | B | A | A | A | A |
| Example 1-2 | J-2 | A-1 | 0.59 | B-2 | 0.10 | C-1/C-2/C-3 | 10/86/4 | B | A | A | A | A |
| Example 1-3 | J-3 | A-1 | 0.59 | B-3 | 0.10 | C-1/C-2/C-3 | 10/86/4 | A | A | A | A | A |
| Example 1-4 | J-4 | A-1 | 0.59 | B-4 | 0.10 | C-1/C-2/C-3 | 10/86/4 | A | A | A | A | A |
| Example 1-5 | J-5 | A-1 | 0.59 | B-5 | 0.10 | C-1/C-2/C-3 | 10/86/4 | A | A | A | A | A |
| Example 1-6 | J-6 | A-1 | 0.59 | B-6 | 0.10 | C-1/C-2/C-3 | 10/86/4 | A | A | A | A | A |
| Example 1-7 | J-7 | A-1 | 0.59 | B-7 | 0.10 | C-1/C-2/C-3 | 10/86/4 | A | A | A | A | A |
| Example 1-8 | J-8 | A-1 | 0.59 | B-8 | 0.10 | C-1/C-2/C-3 | 10/86/4 | A | A | A | A | A |
| Example 1-9 | J-9 | A-2 | 0.59 | B-4 | 0.10 | C-1/C-2/C-3 | 10/86/4 | A | A | A | A | A |
| Example 1-10 | J-10 | A-3 | 0.59 | B-4 | 0.10 | C-1/C-2/C-3 | 10/86/4 | A | A | A | A | A |
| Example 1-11 | J-11 | A-4 | 0.59 | B-4 | 0.10 | C-1/C-2/C-3 | 10/86/4 | A | A | A | A | A |
| Comparative | j-1 | A-1 | 0.59 | b-1 | 0.10 | C-1/C-2/C-3 | 10/86/4 | C | A | B | A | B |
| Example 1-1 | | | | | | | | | | | | |
| Comparative | j-2 | A-1 | 0.59 | b-2 | 0.10 | C-1/C-2/C-3 | 10/86/4 | B | B | B | B | B |
| Example 1-2 | | | | | | | | | | | | |
| Comparative | j-3 | A-1 | 0.59 | b-3 | 0.10 | C-1/C-2/C-3 | 10/86/4 | C | B | B | B | B |
| Example 1-3 | | | | | | | | | | | | |

As is seen from the results shown in Table 2, the compositions for silicon-containing film formation of Examples are capable of forming the silicon-containing film superior in an outgas-inhibiting property, and such a superior silicon-containing film enables formation of a resist pattern exhibiting a superior collapse-inhibiting property and having a favorable configuration.

### INDUSTRIAL APPLICABILITY

The composition for forming a silicon-containing film for EUV lithography of the present invention is capable of forming a silicon-containing film superior in an outgas-inhibiting property, and such a superior silicon-containing film enables a projection mirror, a mask, etc., of the EUV lithography device to be prevented from contamination and also enables formation of a resist pattern exhibiting a superior collapse-inhibiting property and having a favorable configuration. The silicon-containing film for EUV lithography of the present invention is superior in an outgas-inhibiting property and enables formation of a resist pattern exhibiting a superior collapse-inhibiting property and having a favorable configuration. According to the pattern-forming method of the present invention, since a silicon-containing film that is superior in an outgas-inhibiting property and enables formation of a resist pattern exhibiting a superior collapse-inhibiting property and having a favorable configuration is formed, formation of a desired substrate pattern having a favorable configuration is enabled. Therefore, these can be suitably used for EUV lithography, and can be suitably used for manufacture, etc., of semiconductor devices in which further progress of miniaturization is expected in the future.

What is claimed is:

1. A composition for forming a silicon-containing film for EUV lithography comprising:
a polysiloxane;
a compound comprising an onium cation and a sulfonate anion; and
a solvent, wherein
a sum of atomic masses of atoms constituting the sulfonate anion is no less than 240,
the sulfonate anion comprises a sulfonate group and a carbon atom adjacent to the sulfonate group, and
a fluorine atom does not bond to the carbon atom.

2. The composition according to claim 1, wherein the sum of the atomic masses of the atoms constituting the sulfonate anion is no less than 290.

3. The composition according to claim 1, wherein the onium cation is a sulfonium cation, an iodonium cation or a combination thereof.

4. A silicon-containing film for EUV lithography formed from the composition according to claim 1.

5. A pattern-forming method comprising:
applying the composition according to claim 1 onto an upper face side of a substrate; and
patterning a silicon-containing film formed after the applying.

6. The pattern-forming method according to claim 5, wherein the patterning of the silicon-containing film comprises:
applying a resist composition onto an upper face side of the silicon-containing film;
exposing to an extreme ultraviolet ray a resist film formed after the applying of the resist composition;
developing the resist film exposed; and
etching the silicon-containing film using as a mask a resist pattern formed after the developing.

7. The pattern-forming method according to claim 5, further comprising before the applying,
forming an organic underlayer film on at least the upper face side of the substrate.
